(19) United States
(12) Patent Application Publication
(10) Pub. No.: US 2019/0067506 A1
(43) Pub. Date: Feb. 28, 2019

(54) SOLAR CELL AND MANUFACTURING METHOD THEREOF

(71) Applicant: TSO-TUNG KO, Taipei City (TW)

(72) Inventor: TSO-TUNG KO, Taipei City (TW)

(21) Appl. No.: 16/114,235

(22) Filed: Aug. 28, 2018

(30) Foreign Application Priority Data
Aug. 29, 2017 (TW) 106129292

(51) Int. Cl. H01L 31/068; H01L 31/0224; H01L 31/18

(52) U.S. Cl. CPC H01L 31/068; H01L 31/18; H01L 31/022425

(57) ABSTRACT

A solar cell includes an N-type semiconductor, a P-type semiconductor, a top electrode and a bottom electrode. The P-type semiconductor is closely combined with the N-type semiconductor, and a PN junction is formed between the P-type semiconductor and the N-type semiconductor, and the P-type semiconductor includes at least a deep trench. The top electrode is connected to the N-type semiconductor, and the bottom electrode is connected to the P-type semiconductor, and the bottom electrode includes at least a microelectrode column embedded into the deep trench and electrically connected to the P-type semiconductor. When the P-type semiconductor has a diffusion length T, the distance between the PN junction and an upper end of the microelectrode column is not greater than ½T or half T.

### BACKGROUND OF THE INVENTION

### Field of the Invention

The present invention relates to a solar cell and its manufacturing method, in particular to the solar cell with a microelectrode column and its manufacturing method, and the upper end of the microelectrode column is disposed proximate to a P/N junction of the solar cell, and the distance between the upper end of the microelectrode column and the P/N junction does not exceed half of the diffusion length.

### Description of Related Art

With reference to FIGS. 1 and 2 for a perspective view and a cross-sectional view of a conventional solar cell 10 respectively, the solar cell 10 is produced by a semiconductor manufacturing process and its principle of electric power generation resides on projecting sunlight onto the solar cell 10, so that the solar cell 10 absorbs the solar energy by a P-type semiconductor 11 and a N-type semiconductor 12 as shown in FIG. 1 to produce electrons (negative electrode) and holes (positive electrode), and then an electric field across the PN interface 13 drives the electrons to move from the P-type semiconductor 11 to the N-type semiconductor 12, and then transmits a load through a wire 14. More specifically, after the solar cell 10 absorbs the solar energy, the free electrons 8 in the P-type semiconductor 11 are activated by the sunlight to drift to the PN junction 13 and enter into the N-type semiconductor, and then the free electrons 8 are conducted by the top electrode 12A to the external load. The free electrons 8 are sent to the bottom electrode 11A and returned from the bottom electrode 11A to the P-type semiconductor 11 to form a current.

Since the thicker P-type semiconductor 11 will cause the free electrons 8 to pass a long high-resistance path, and the free electrons 8 will be combined with the holes of the P-type semiconductor 11 again (or the free electrons 8 disappear), so that a large quantity of free electrons 8 will be unable to drift to the PN junction 13. For example, FIG. 2 has a virtual line 15 precisely below the PN junction 13, and the distance between the virtual line 15 and the PN junction 13 is the diffusion length of the free electrons 8 in the P-type semiconductor 11. Wherein, the free electrons 8 above the virtual line 15 statistically have a higher chance to be drifted to the PN junction 13. On the other hand, the chance for the free electrons 8 below the virtual line 15 to drift to the PN junction 13 is almost impossible, because the chance for the free electrons to drift a distance exceeding the diffusion length while maintaining its free state without being recombined or absorbed approaches zero, so that most free electrons activated by the sunlight cannot play their role, and a vast majority of the absorbed energy is wasted. As a result, the photoelectric conversion efficiency of the solar cell 10 is low. In general, the photoelectric conversion efficiency of this case is just 20% only.

Therefore, it is a main subject or challenge for manufacturers of the related industry to overcome the issues regarding the disappearance of free electrons 8 and the too-long resistance path in the P-type semiconductor 11 and improves the photoelectric conversion efficiency of the solar cell.

### SUMMARY OF THE INVENTION

Therefore, it is a primary objective of the present invention to provide a solar cell capable of reducing the disappearance of free electrons and shortening the high resistance path through which the free electrons pass. In addition, the solar cell has relatively higher photoelectric conversion efficiency.

To achieve the aforementioned and other objectives, the present invention provides a solar cell comprising an N-type semiconductor, a P-type semiconductor, a top electrode and a bottom electrode. Wherein, the P-type semiconductor is tightly combined with the N-type semiconductor, and a PN junction is formed between the P-type semiconductor and the N-type semiconductor, and the P-type semiconductor includes at least a deep trench. The top electrode is coupled to the N-type semiconductor, and the bottom electrode is coupled to the P-type semiconductor, and the bottom electrode includes at least a microelectrode column embedded into the deep trench, and the microelectrode column and the P-type semiconductor constitute an electrical connection. Wherein, when the P-type semiconductor has a diffusion length of T, the distance between the PN junction and the upper end of the microelectrode column is not greater than ½T or half T.

The present invention also provides a solar cell comprising an N-type semiconductor, a P-type semiconductor, a top electrode and a bottom electrode. The P-type semiconductor is tightly combined with the N-type semiconductor, and a PN junction is formed between the P-type semiconductor and the N-type semiconductor, and the N-type semiconductor includes at least a deep trench. The top electrode is coupled to the N-type semiconductor, and the top electrode includes at least a microelectrode column embedded into the deep trench. The bottom electrode is coupled to the P-type semiconductor. Wherein, when the N-type semiconductor has a diffusion length T, the distance between the PN junction and the upper end of the microelectrode column is not greater than ½T or half T.

In the solar cell, the microelectrode column is a hollow structure, and the external surface of the microelectrode column is closely attached to the deep trench so that the external surface of the microelectrode column and the P-type semiconductor form an electrical connection.

In the solar cell, both sides of the deep trench are parallel to each other, or two extension lines on both sides of the deep trench form an acute angle.

In the solar cell, the microelectrode column has a cross section in a substantially rectangular, square, rhombus, circular, elliptic, polygonal, or wavy shape.

In the solar cell, a preferred distance between two adjacent microelectrode columns is one diffusion length of a wafer or smaller than the diffusion length which is equal to or smaller than T.

The present invention also provides a manufacturing method of a solar cell, and the manufacturing method comprises the steps of: providing an N-type semiconductor coupled to one of the surfaces of a P-type semiconductor to form a PN junction between the P-type semiconductor and the N-type semiconductor; providing an oxide layer attached onto the other side of the P-type semiconductor; providing a plurality of photoresist layers covering the oxide layer; etching the oxide layer not covered by the photoresist layer; removing the photoresist layer; etching the P-type semiconductor not covered by the oxide layer to form at least a deep trench; removing the oxide layer; and providing a bottom electrode coupled to the P-type semiconductor; wherein the bottom electrode comprises at least a microelectrode column embedded into the deep trench; when a diffusion length of the P-type semiconductor is T, the distance between the PN junction and the upper end of the microelectrode column is not greater than ½T or half T.

In the manufacturing method of a solar cell, the microelectrode column is a hollow structure, and the external surface of the microelectrode column is attached closely to the deep trench.

In the manufacturing method of a solar cell, a preferred distance between two adjacent microelectrode columns is one diffusion length of a wafer which is equal to T, or it can be smaller than T.

### BRIEF DESCRIPTION OF THE FIGURES

FIG. 1 is a perspective view of a conventional solar cell 10;

FIG. 2 is a cross-sectional view of a conventional solar cell 10;

FIG. 3A is a perspective view of a solar cell 20 in accordance with an embodiment of the present invention;

FIG. 3B is a cross-sectional view of a solar cell 20 in accordance with an embodiment of the present invention;

FIG. 3C is a schematic view of a deep trench 210 of a P-type semiconductor of the present invention;

FIG. 3D is a comparison chart of the potential photoelectric conversion efficiencies utilizing microelectrode columns 271 with different heights in accordance with the present invention;

FIG. 3E is a schematic view of a bottom electrode 27 having only one microelectrode column 271 in accordance with the present invention;

FIGS. 4A, 4B and 4C are schematic views of microelectrode columns 271 with different cross-sectional shapes in accordance with the present invention;

FIG. 5A is a cross-sectional view of a solar cell 30 in accordance with another embodiment of the present invention;

FIG. 5B is a cross-sectional view of a solar cell 40 in accordance with a further embodiment of the present invention;

FIG. 5C is a cross-sectional view of a solar cell 50 in accordance with another embodiment of the present invention;

FIG. 6 is a cross-sectional view of a solar cell 60 in accordance with another embodiment of the present invention; and

FIGS. 7A˜7H are schematic views showing the steps of a manufacturing method of the solar cell 20 in accordance with the present invention.

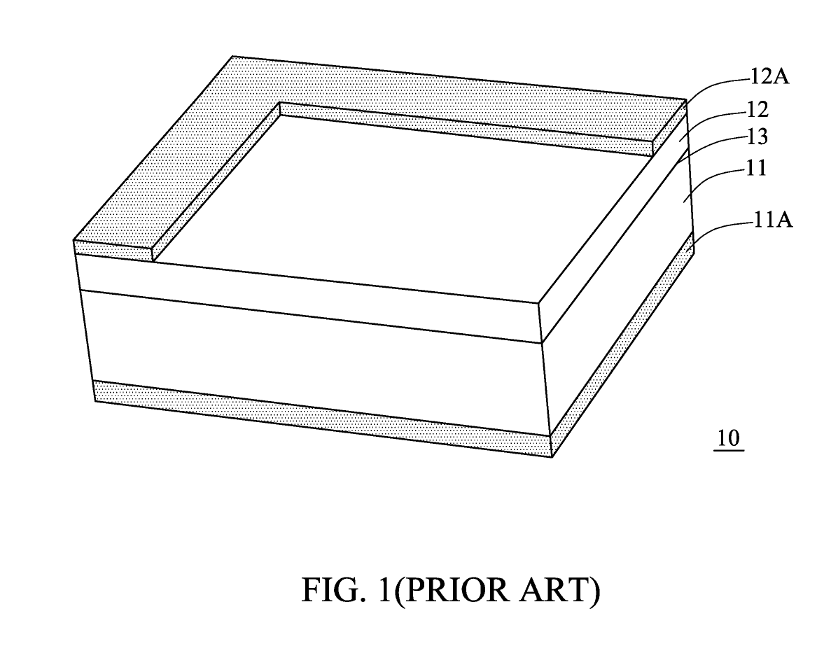

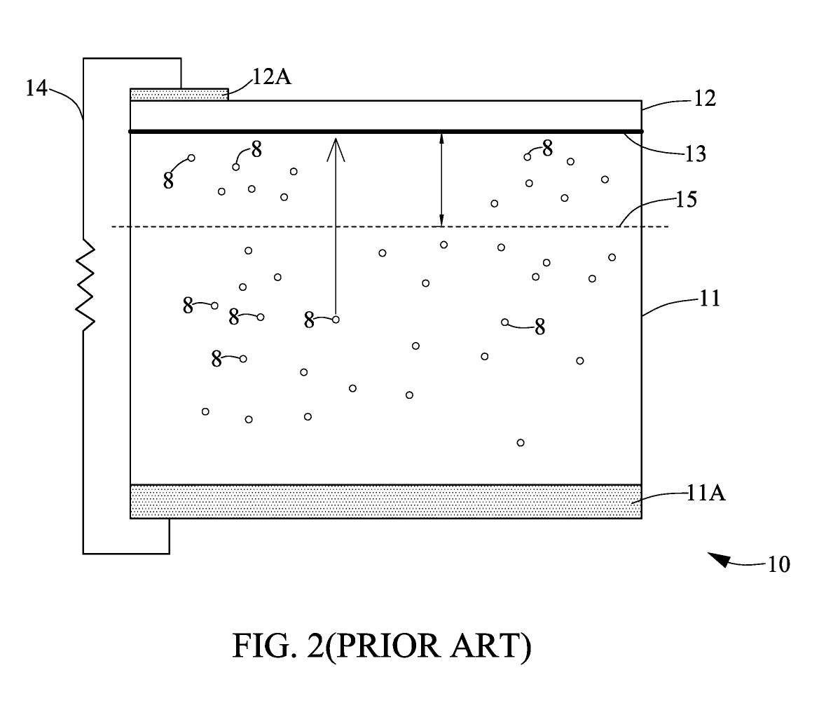

### DESCRIPTION OF THE INVENTION

To make it easier for our examiner to understand the objective, technical characteristics, structure, innovative features, and performance of the invention, we use preferred embodiments together with the attached figures for the detailed description of the invention. It is intended that the embodiments and figures disclosed herein are to be considered illustrative rather than restrictive.

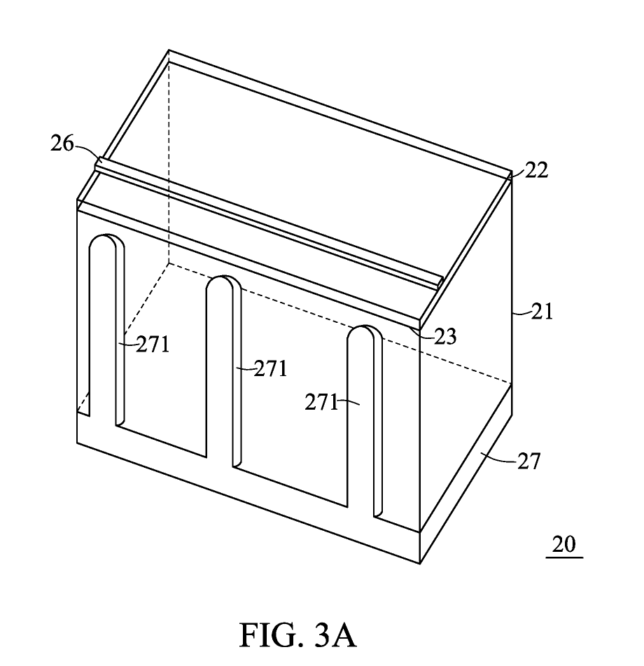

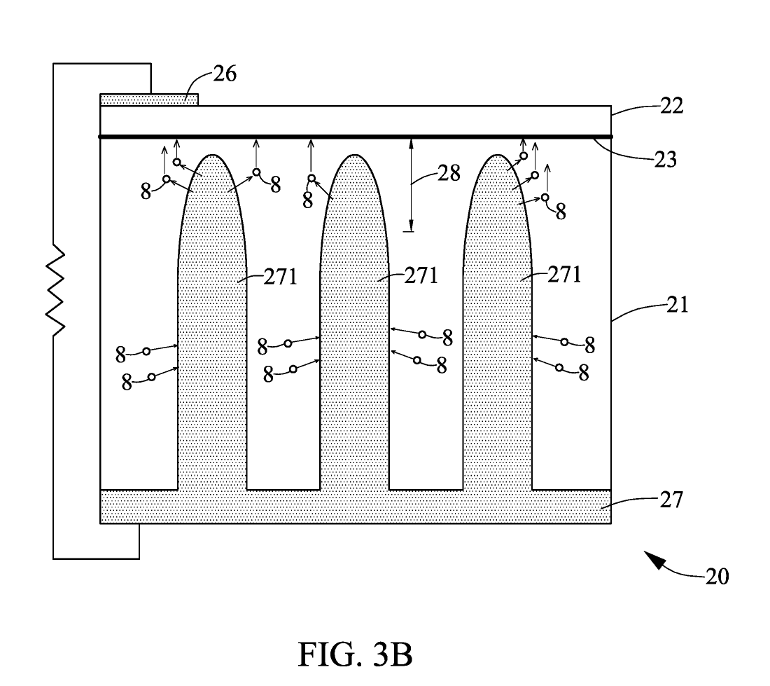

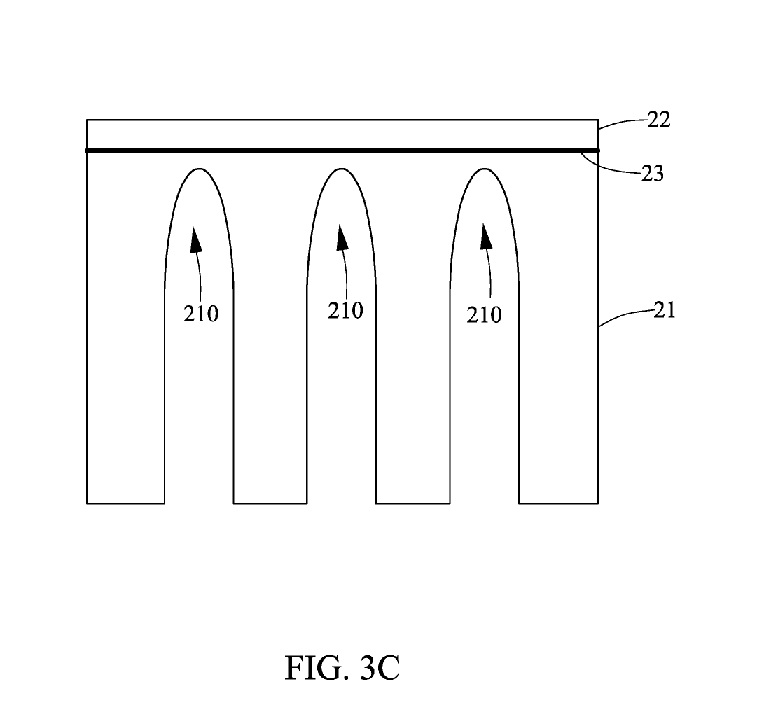

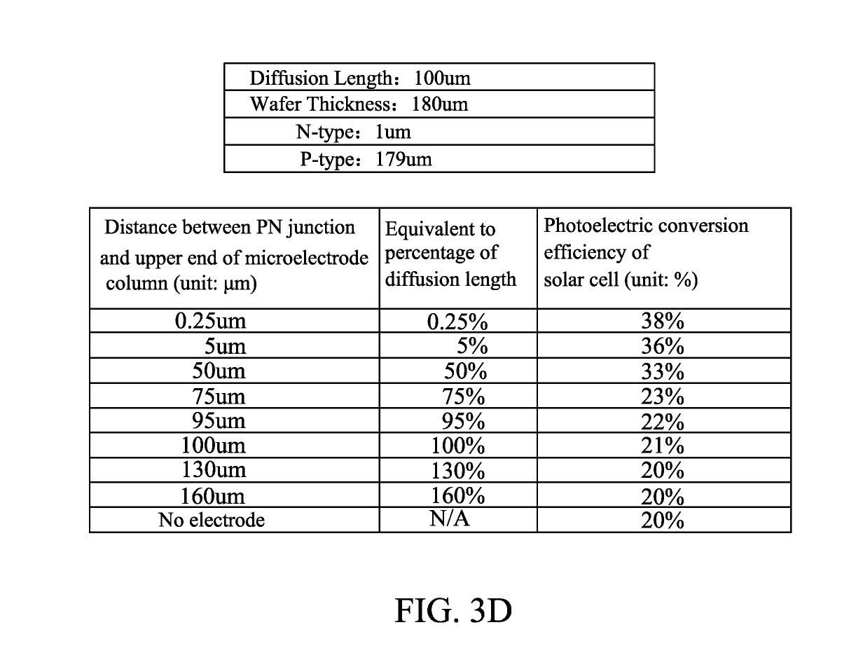

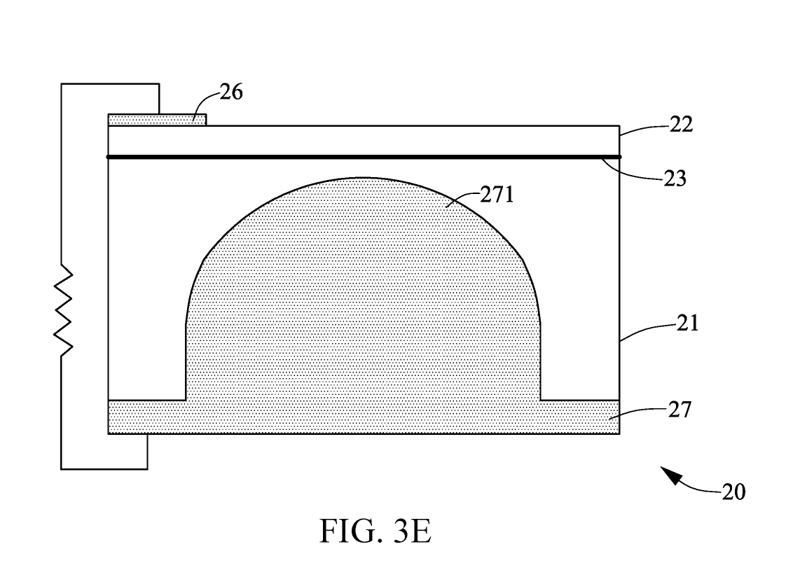

With reference to FIGS. 3A and 3B for a perspective view and a cross-sectional view of a solar cell 20 in accordance with an embodiment of the present invention respectively, the solar cell 20 comprises an N-type semiconductor 22, a P-type semiconductor 21, a top electrode 26 and a bottom electrode 27, and the P-type semiconductor 21 is closely combined with the N-type semiconductor 22, and a PN junction 23 is formed between the P-type semiconductor 21 and the N-type semiconductor 22, and the P-type semiconductor 21 comprises at least a deep trench 210 (as shown in FIG. 3C). In addition, the top electrode 26 is coupled to the N-type semiconductor 22, and the bottom electrode 27 is coupled to the P-type semiconductor 21. The bottom electrode 27 comprises at least a microelectrode column 271 (there are three microelectrode columns 271 as shown in FIGS. 3A and 3B and used an example for illustrating the present invention), and the microelectrode columns 271 are embedded into the deep trench 210. Wherein, when the P-type semiconductor 21 has a diffusion length T, the distance between the PN junction and the upper end of the microelectrode column is not greater than ½T or half T. For example, if the P-type semiconductor 21 has a diffusion length of 100 um, the distance between the PN junction 23 and the upper end of the microelectrode column 271 will be smaller than or equal to 50 um, which is smaller than or equal to half of the diffusion length. Therefore, after the solar cell 20 absorbs solar energy, the P-type semiconductor 21 will be activated by the sunlight to produce free electrons 8. Wherein, the free electrons 8 near the PN junction 23 can drift to the PN junction 23 more easily, and the free electrons 8 with distance farther from the PN junction 23 may be conducted to the upper end of the microelectrode column 271 through the microelectrode column 271. Specifically, the microelectrode column 271 may be considered as a bridge for conducting the free electrons 8, and the free electrons 8 originally having a farther distance from the PN junction 23 may be absorbed by the microelectrode column 271. The absorbed free electrons 8 moves along the path of the microelectrode column 271 and reaches the upper end of the microelectrode column 271 (wherein the upper end is disposed at a position with a distance from the PN junction 23 which is not greater than 50 um, or not greater than half of the diffusion length in this embodiment). The absorbed free electrons 8 move from the upper end of microelectrode column 271 to an area near the PN junction 23, so that the free electrons 8 with a distance farther from the PN junction 23 do not need to pass through a long high-resistance path, and the free electrons 8 will not be combined with the holes of the P-type semiconductor 21 again easily (since the free electrons 8 will be absorbed by the microelectrode column 271 first).

In the description above, the distance between the PN junction 23 of the solar cell 20 and the upper end of the microelectrode column 271 is not greater than half of the diffusion length. If such distance is not greater than half of the diffusion length, the photoelectric conversion efficiency of the solar cell 20 will be improved significantly (over 30%), and the detailed description will be given below:

With reference to FIG. 3D for a comparison chart of the photoelectric conversion efficiencies of the microelectrode columns 271 with different heights, the inventor of the present invention have calculated the photoelectric conversion efficiency of each solar cell using a plurality of microelectrode columns 271 of different heights (the higher the microelectrode column 271, the shorter the distance between the PN junction 23 and the upper end of the microelectrode column 271), and the final results are listed in the comparison chart as shown in FIG. 3D. In the comparison chart as shown in FIG. 3D, if the wafer thickness is equal to 180 um (wherein the N-type semiconductor has a thickness of 1 um, the P-type semiconductor has a thickness of 179 um, and the wafer has a diffusion length of 100 um), and the distance between the PN junction 23 and the upper end of the microelectrode column 271 is 0.25 um, then the photoelectric conversion efficiency of the solar cell will be 38%. If the distance is 5 um, then the photoelectric conversion efficiency will be 36%, and if the distance is 50 um, then the photoelectric conversion efficiency will be 33%. However, if the distance between the PN junction 23 and the upper end of the microelectrode column 271 exceeds 50 um, then the photoelectric conversion efficiency of the solar cell will be less than 30%. For example, if the distance is 75 um, then the photoelectric conversion efficiency will be 23%, and if the distance is 95 um, then the photoelectric conversion efficiency will be 22%, and if the distance is 100 um, then the photoelectric conversion efficiency will be 21%. Therefore, if the distance between the PN junction 23 and the upper end of the microelectrode column 271 is not greater than 50 um (which is not greater than half of the diffusion length), then the solar cell will have significantly improved photoelectric conversion efficiency. Compared with the conventional solar cell 10 (whose photoelectric conversion efficiency is generally 20%), the solar cell according to this embodiment of the invention has an excellent photoelectric conversion efficiency (over 30%).

When the solar cell 20 has a plurality of microelectrode columns 271, the distance between two adjacent microelectrode columns 271 is preferably not greater than the diffusion length. For example, if the thickness of the N-type semiconductor 22 combined with the P-type semiconductor 21 is 180 um (when the wafer has a thickness of 180 um, and the diffusion length of the wafer is 100 um), then the distance between two adjacent microelectrode columns 271 will preferably not be greater than 100 um, which is smaller than or equal to the diffusion length. Therefore, the free electrons 8 have a very high chance to reach one of the two adjacent microelectrode columns 271 within the diffusion length of 100 um, and the free electrons 8 will not be combined with the holes and disappear.

With reference to FIG. 3E for a schematic view of a bottom electrode 27 having only one microelectrode column 271, the solar cell 20 as shown in FIGS. 3A and 3B have three microelectrode columns 271. However, the persons having ordinary skill in the art should know that the solar cell 20 may have only one microelectrode column 271 to achieve the effect of conducting the free electrons 8 similarly.

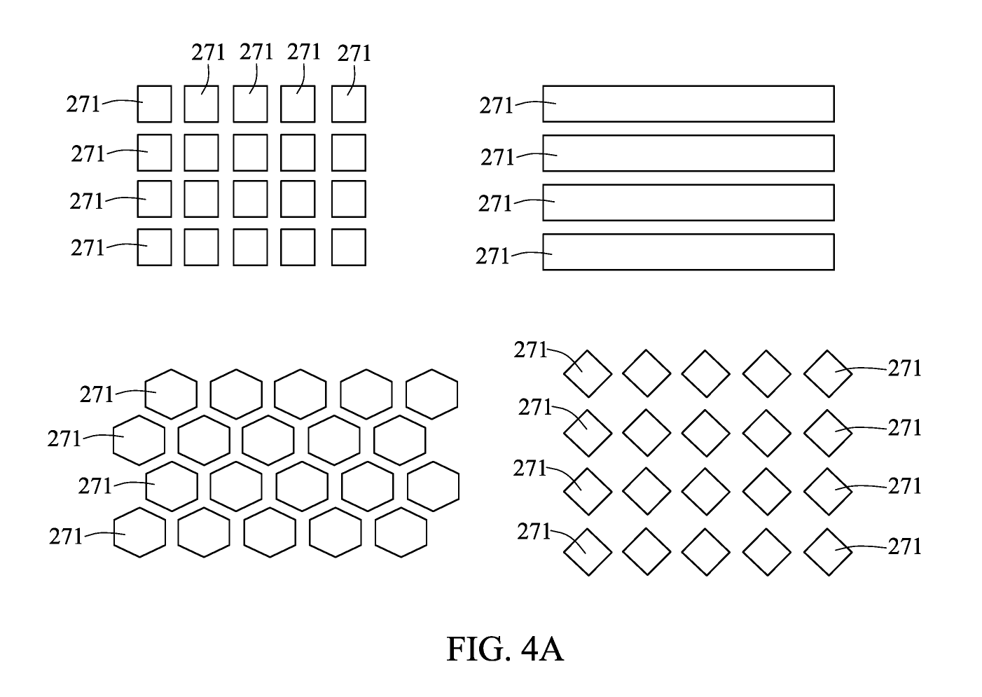

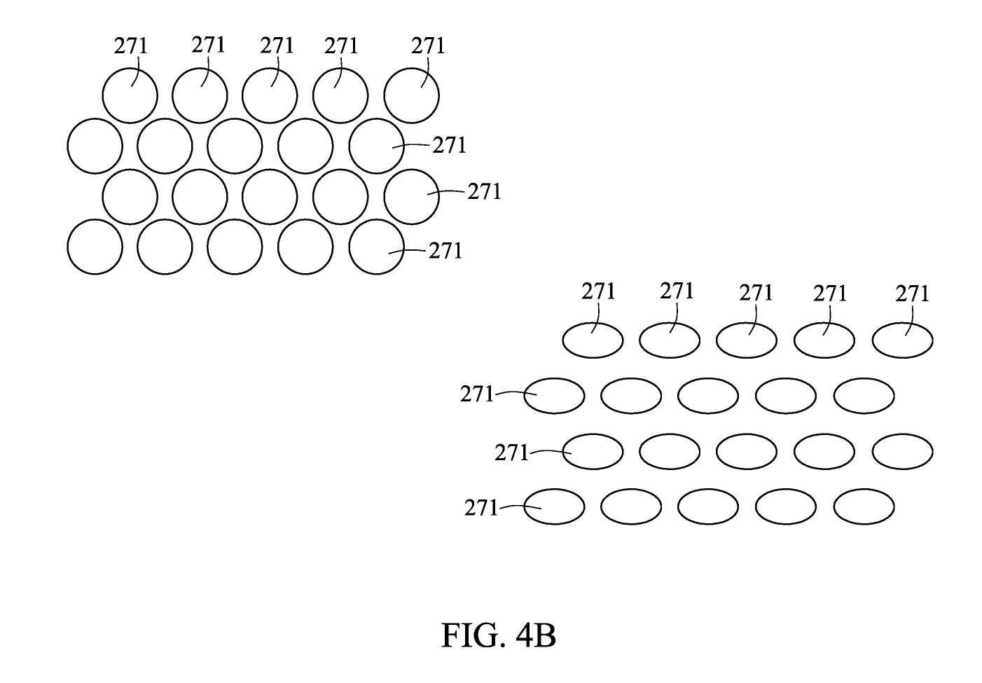

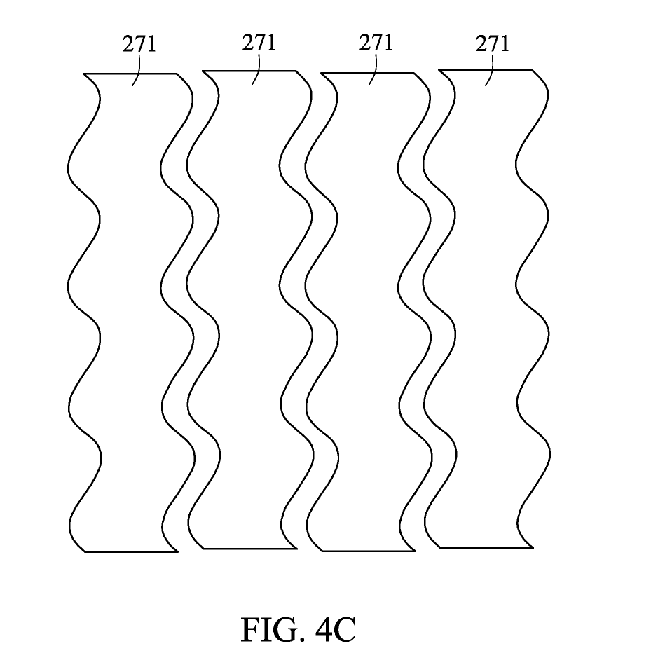

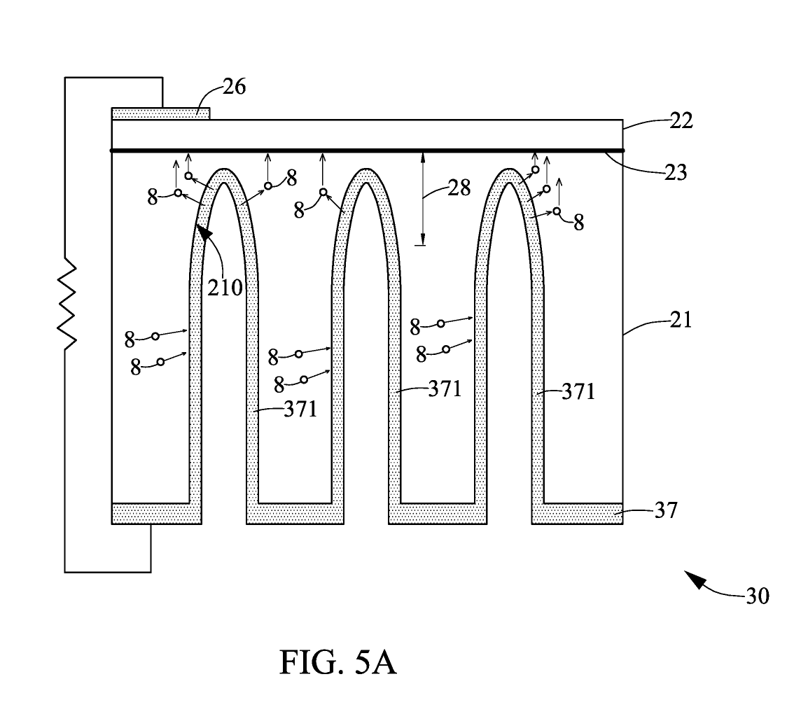

With reference to FIGS. 4A, 4B and 4C for schematic views of microelectrode columns 271 with various different cross-sectional shapes respectively, FIG. 4A shows a microelectrode column 271 with a polygonal cross-sectional shape such as a rectangular, rhombus, square or hexagonal shape; FIG. 4B shows a microelectrode column 271 with a circular or elliptic cross-sectional shape; and FIG. 4C shows a microelectrode column 271 with a wavy cross-sectional shape. Although the microelectrode column 271 may come with different cross-sectional shapes, these microelectrode columns 271 can help the free electrons 8 to drift to the PN junction as long as the distance between the PN junction 23 and the upper end of the microelectrode column 271 is not greater than half of the diffusion length.

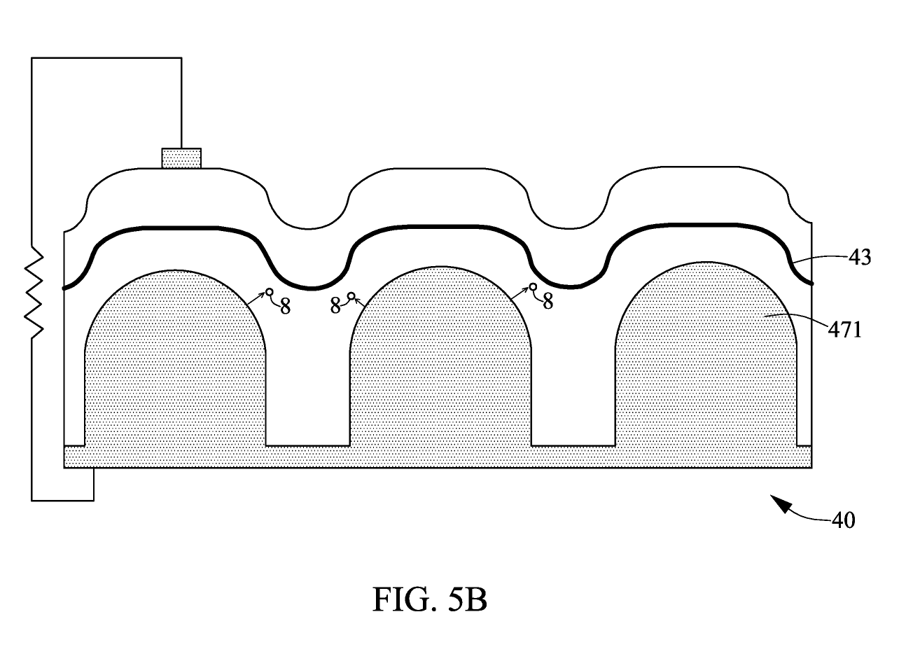

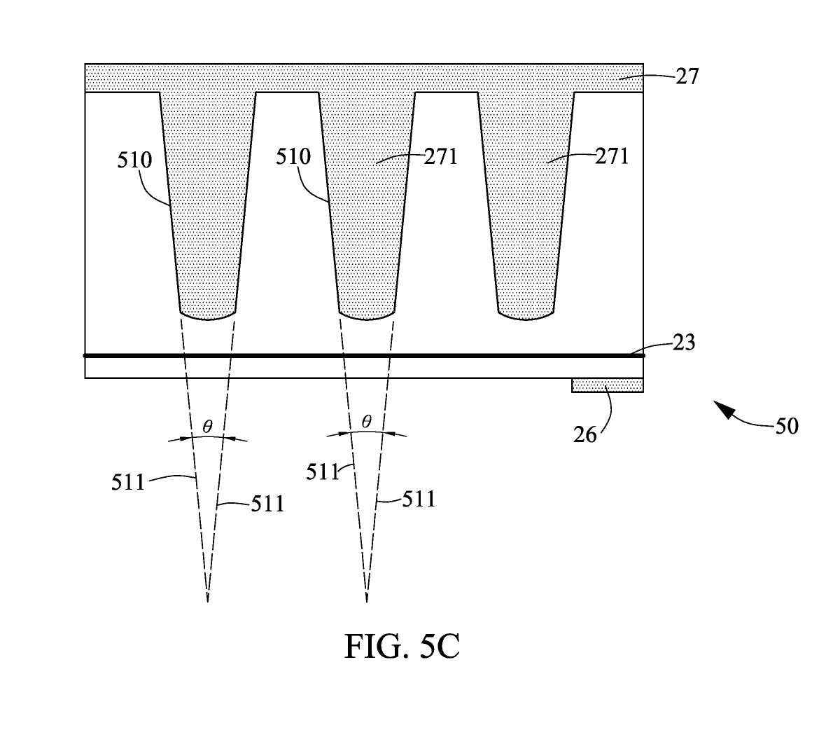

With reference to FIG. 5A for a cross-sectional view of a solar cell 30 in accordance with another embodiment of the present invention, the solar cell 30 is derived from the solar cell 20, and the main difference of the two resides on that the microelectrode column 371 of the solar cell 30 is a hollow structure, and the external surface of the microelectrode column 371 is attached closely to the deep trench 210, and the distance between the upper end and the PN junction 23 is also not greater than half of the diffusion length. The microelectrode column 371 with a hollow structure also can act as a bridge of conducting free electrons 8 to assist more free electrons 8 to drift to the PN junction. Since the microelectrode column 371 is a hollow structure, the bottom electrode 37 of the solar cell 30 may be manufactured with a small amount of metal to reduce the manufacturing cost of the present invention significantly.

With reference to FIG. 5B for a cross-sectional view of a solar cell 40 in accordance with a further embodiment of the present invention, the solar cell 40 is also derived from the solar cell 20. Wherein, the PN junction of the solar cell 40 maintains a relative distance from the upper end of the microelectrode column 471. Specifically, if the upper end of the microelectrode column 471 is in a circular arc shape, the PN junction 43 of the solar cell 40 is equidistantly deviated from the upper end. In other words, the PN junction 43 has become an offset surface of the upper end, so that both sides of the upper end of the microelectrode column 471 are closer to the PN junction 43. After the free electrons 8 leave from either side of the upper end, the free electrons 8 may drift to the PN junction easily.

With reference to FIG. 5C for a cross-sectional view of a solar cell 50 in accordance with another embodiment of the present invention, the solar cell 50 is also derived from the solar cell 20, and the difference between the two resides on that two extension lines 511 on both sides of a deep trench 510 of the solar cell 50 form an acute angle θ. Therefore, the slightly tilted deep trench 510 can assist the electrically conductive material to deposit (and the deposited electrically conductive material will form the microelectrode column 271).

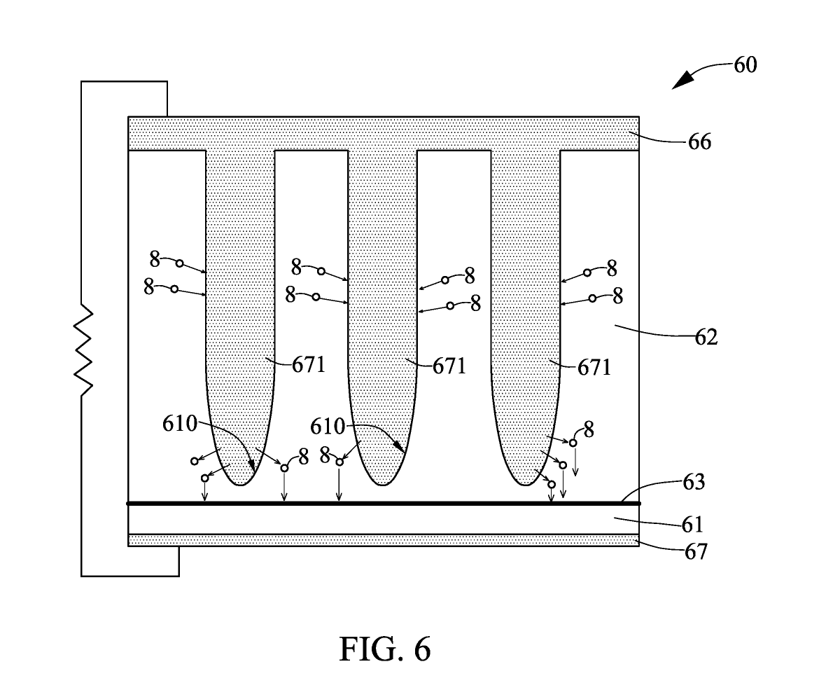

With reference to FIG. 6 for a cross-sectional view of a solar cell 60 in accordance with a further embodiment of the present invention, the solar cell 60 is also derived from the solar cell 20, and the main difference resides on that the P-type semiconductor 21 and the N-type semiconductor 22 are swapped, and the technical characteristics are described below:

The solar cell 60 comprises an N-type semiconductor 62, a P-type semiconductor 61, a top electrode 66 and a bottom electrode 67, wherein the P-type semiconductor 61 is closely combined with the N-type semiconductor 62, and a PN junction 63 is formed between the P-type semiconductor 61 and the N-type semiconductor 62, and the N-type semiconductor 62 includes at least a deep trench 610. In addition, the top electrode 66 is coupled to the N-type semiconductor 62, and the bottom electrode 67 is coupled to the P-type semiconductor 61. In addition, the top electrode 66 comprises at least a microelectrode column 671 (wherein there are three microelectrode column 671 in FIG. 6 for illustrating the invention, and the microelectrode columns 671 are embedded into the deep trench 610. If the N-type semiconductor 62 has a diffusion length T, then the distance between the PN junction 63 and the upper end of the microelectrode column 671 will not be greater than ½T or half T. In other words, the distance between the PN junction 63 and the upper end of the microelectrode column 671 is not greater than half of the diffusion length. Similarly, the microelectrode column 671 may be considered as a bridge for conducting the free electrons 8, and the free electrons 8 originally having a farther distance from the PN junction 63 will be absorbed by the microelectrode column 671. The absorbed free electrons 8 moves in a path along the microelectrode column 671 and reaches the upper end of the microelectrode column 671, and then the absorbed free electrons 8 leave from the upper end of the microelectrode column 671. Now, the free electrons 8 are very close to the PN junction 63. Therefore, the free electrons 8 originally having a farther distance from the PN junction 63 no longer need to pass through the long high-resistance path, and the solar cell 60 of this embodiment has excellent photoelectric conversion efficiency. If the solar cell 60 has a plurality of microelectrode columns 671, the distance between two adjacent microelectrode columns 671 will also be not greater than the diffusion length to ensure the free electrons 8 at the bottom can reach the microelectrode columns 671.

In addition, a manufacturing method of a solar cell 20 in accordance with the present invention comprises the following steps:

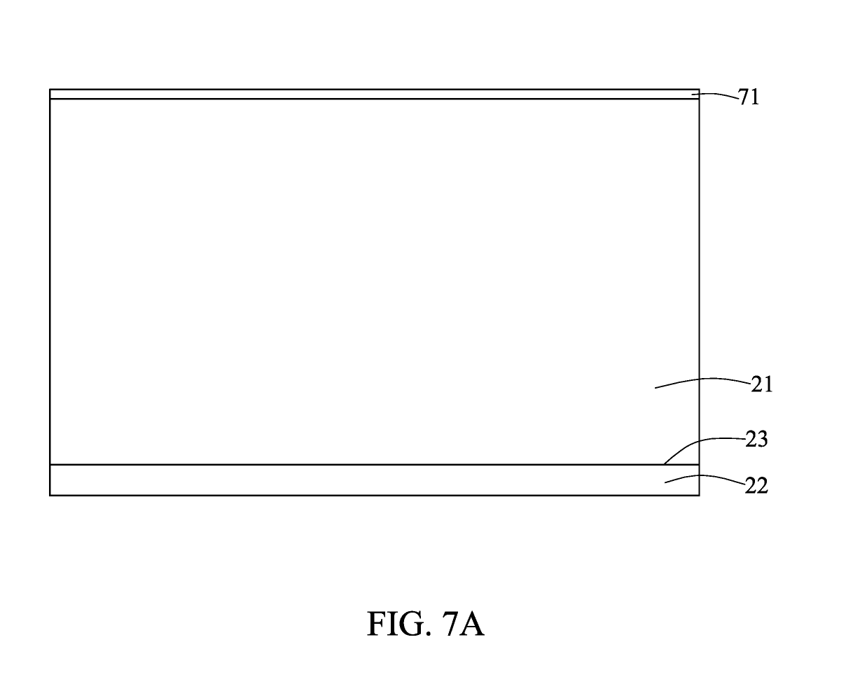

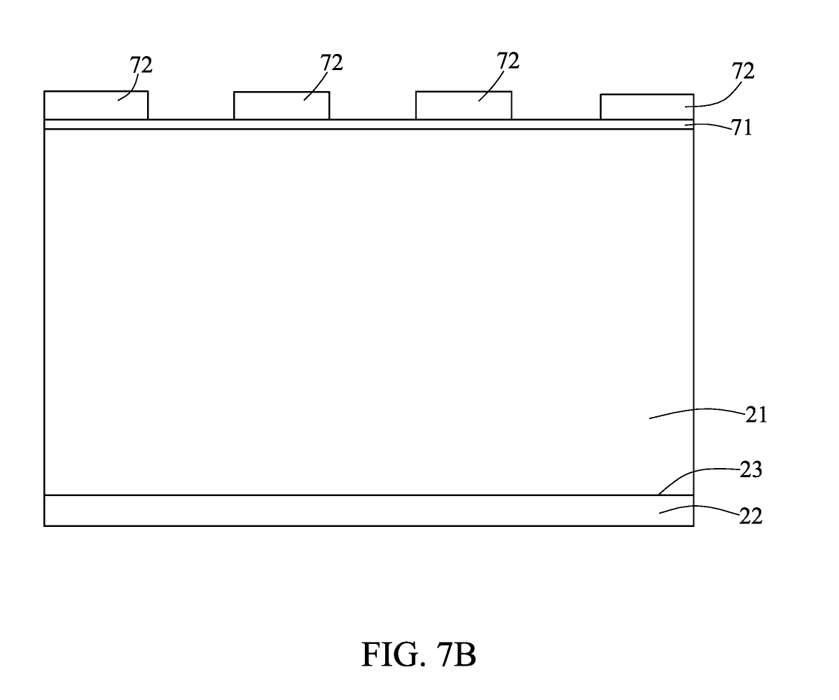

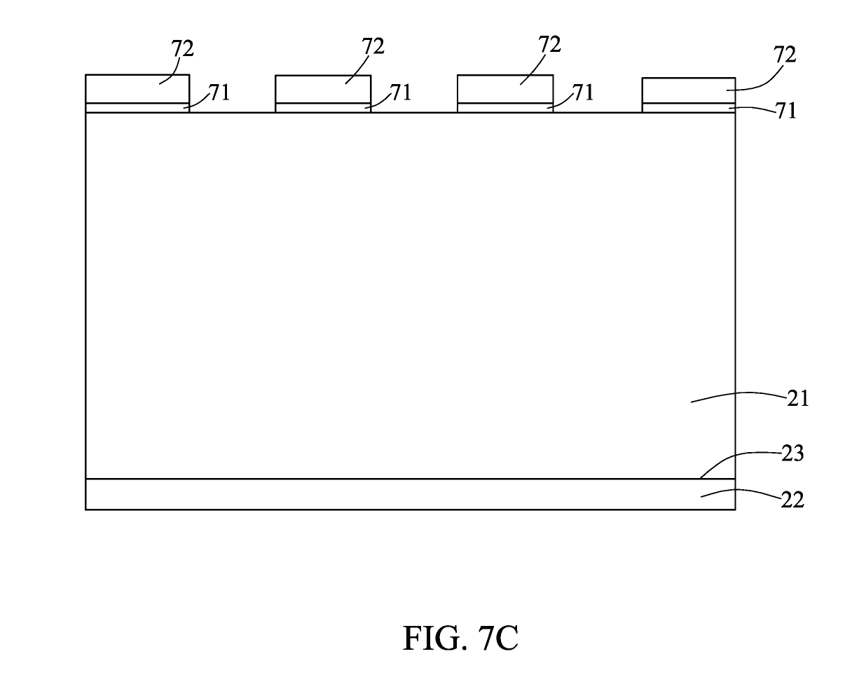

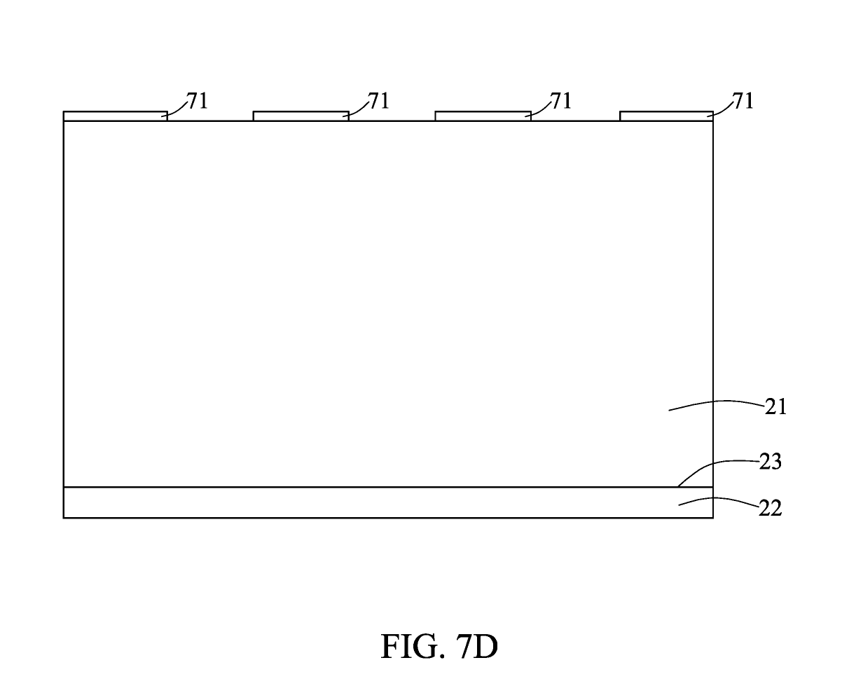

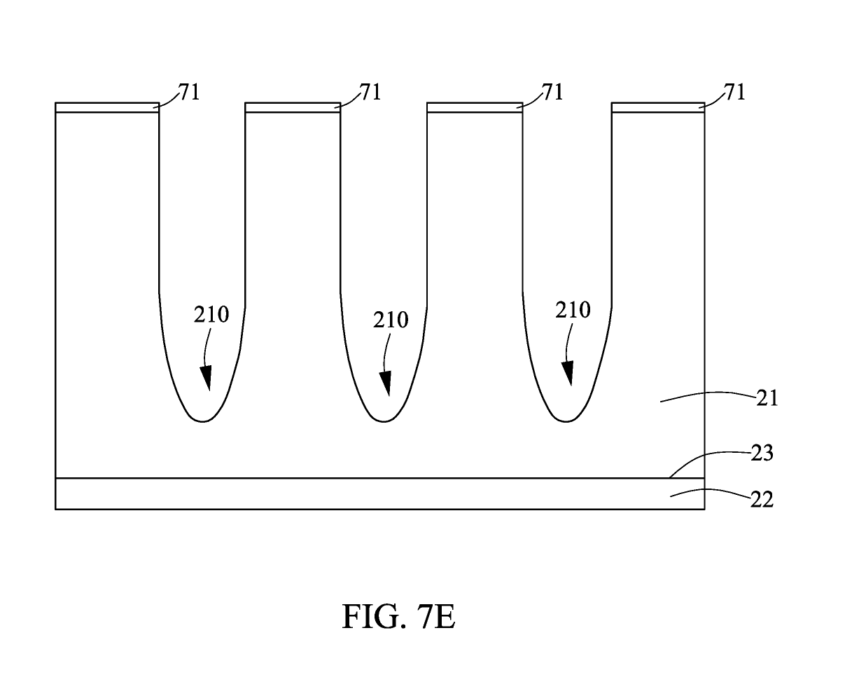

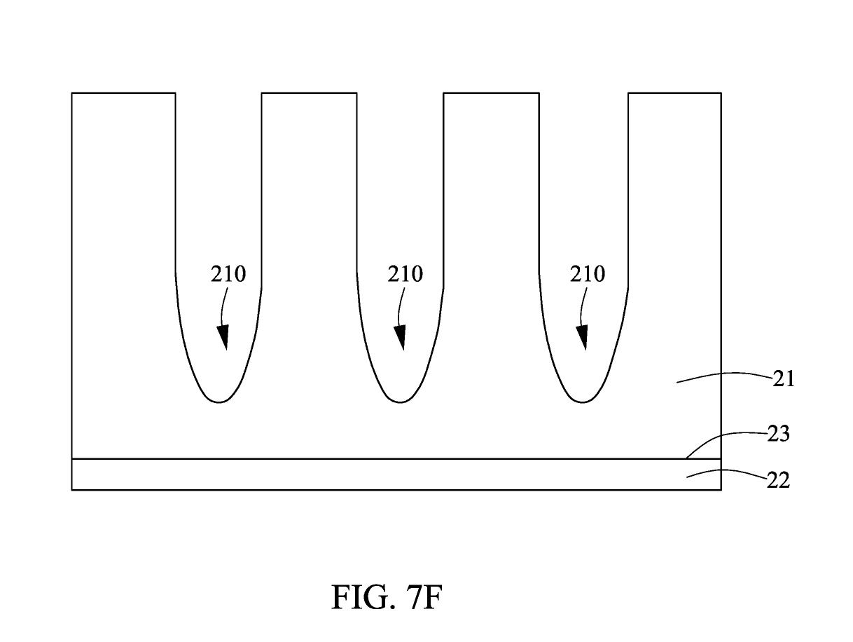

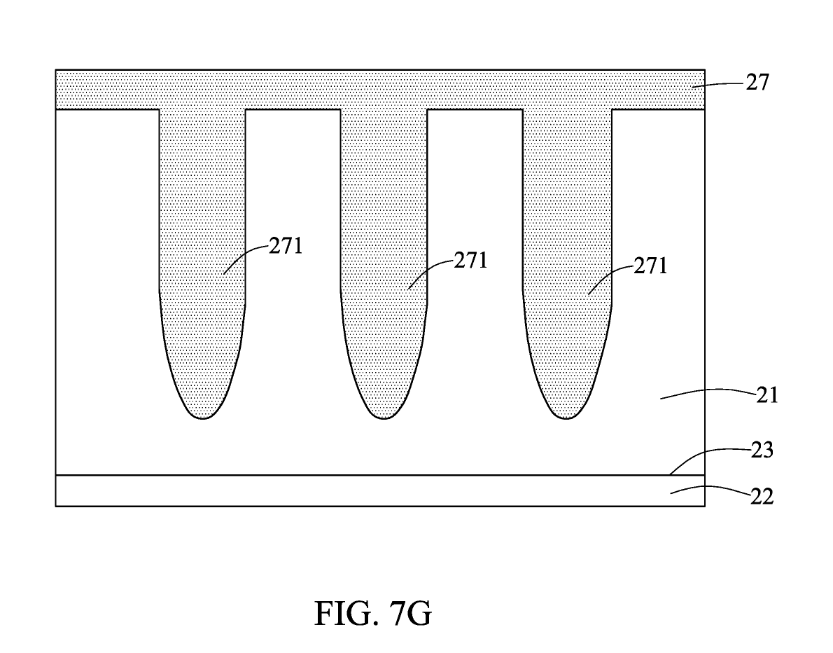

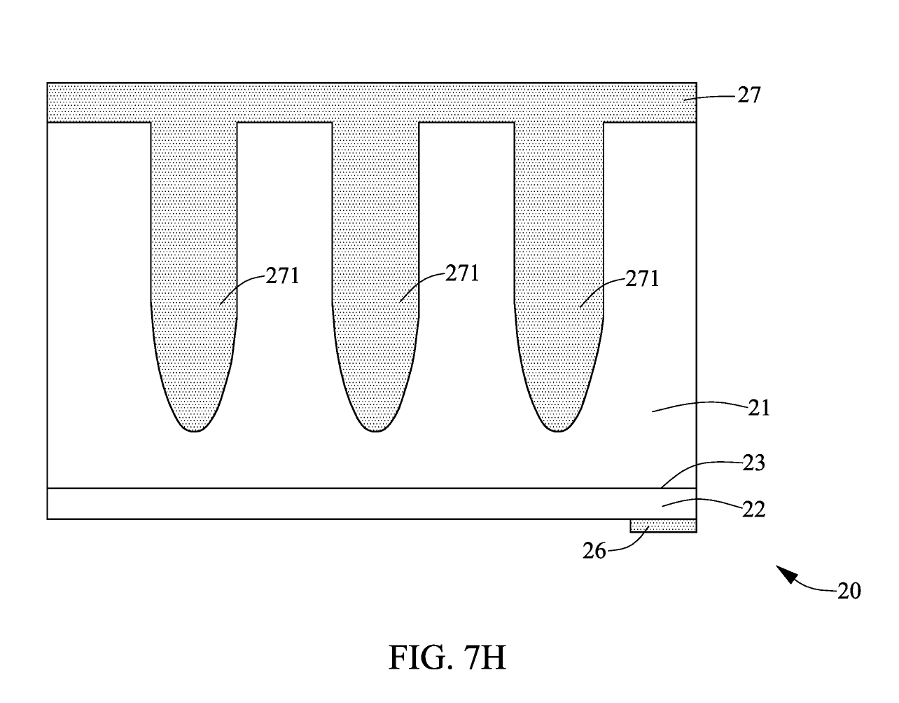

Firstly, an N-type semiconductor 22 is provided to engage with one of the sides of a P-type semiconductor 21, and a PN junction 23 is formed between the P-type semiconductor 21 and the N-type semiconductor 22. In FIG. 7A, an oxide layer 71 is provided and attached onto the other side of the P-type semiconductor 21. In FIG. 7B, a plurality of photoresist layers 72 are provided and covered onto the oxide layer 71. In FIG. 7C, the oxide layer 71 not covered by the photoresist layer 72 is etched. In FIG. 7D, the photoresist layer 72 is removed. In FIG. 7E, the P-type semiconductor 21 not covered by the oxide layer 71 is etched to form at least a deep trench 210. In FIG. 7F, the oxide layer 71 is removed. In FIG. 7G, a bottom electrode 27 is provided and coupled to the P-type semiconductor, wherein the bottom electrode 27 comprises at least a microelectrode column 271 embedded into the deep trench 210 (each microelectrode column 271 corresponds to a deep trench 210, and the microelectrode column 271 may be formed by depositing an electrically conductive material into the deep trench 210). In FIG. 7H, a top electrode 26 is provided and coupled to the N-type semiconductor 22. If the P-type semiconductor 21 has a diffusion length T, then the distance between the PN junction 23 and the upper end of the microelectrode column 271 will not be greater than ½T or half T. The solar cell 20 of this embodiment is manufactured according to the aforementioned steps.

Before the electrically conductive material is deposited to form the microelectrode column 271, a conductive barrier layer may be deposited onto a surface of the deep trench 210 first, wherein the barrier layer may be made of a material such as titanium nitride (TiN) or titanium tungsten (TiW) for protecting the electrically conductive material from further diffusing into the P-type semiconductor. If aluminum is used as the electrically conductive material, a small amount of silicon may be added into the electrically conductive material first, since the small amount of silicon can prevent aluminum from diffusing into a chip and damaging the chip. Therefore, the barrier layer may be omitted to save a substantial manufacturing cost.

While the invention has been described by means of specific embodiments, numerous modifications and variations could be made thereto by those skilled in the art without departing from the scope and spirit of the invention set forth in the claims.

What is claimed is:

1. A solar cell, comprising:
a N-type semiconductor;
a P-type semiconductor, closely combined with the N-type semiconductor, and a PN junction being formed between the P-type semiconductor and the N-type semiconductor, and the P-type semiconductor including at least a deep trench;
a top electrode, coupled to the N-type semiconductor;
a bottom electrode, coupled to the P-type semiconductor, and including at least a microelectrode column embedded into the deep trench;
wherein, when the P-type semiconductor has a diffusion length T, the distance between the PN junction and an upper end of the microelectrode column is not greater than half T.

2. The solar cell of claim 1, wherein the microelectrode column is a hollow structure, and an external surface of the microelectrode column is closely attached to the deep trench and electrically coupled to the P-type semiconductor.

3. The solar cell of claim 1, wherein the deep trench has two extension lines formed on both sides of the deep trench to define an acute angle.

4. The solar cell of claim 1, wherein the microelectrode column has a cross section in a substantially rectangular, square, rhombus, circular, polygonal, elliptic or wavy shape.

5. The solar cell of claim 1, wherein the distance between two adjacent microelectrode columns is not greater than T.

6. A manufacturing method of a solar cell, comprising the steps of:
providing an N-type semiconductor coupled to one of the surfaces of a P-type semiconductor, and forming a PN junction between the P-type semiconductor and the N-type semiconductor;
providing an oxide layer attached onto the other side of the P-type semiconductor;
providing a plurality of photoresist layers covering the oxide layer;
etching the oxide layer not covered by the photoresist layer;
removing the photoresist layer;
etching the P-type semiconductor not covered by the oxide layer to form at least a deep trench;
removing the oxide layer; and
providing a bottom electrode coupled to the P-type semiconductor;
wherein the bottom electrode comprises at least a microelectrode column embedded into the deep trench; when a diffusion length of the P-type semiconductor is T, the distance between the PN junction and the upper end of the microelectrode column is not greater than half T.

7. The manufacturing method of a solar cell according to claim 6, wherein the microelectrode column is a hollow structure, and an external surface of the microelectrode column is closely attached to the deep trench, and the microelectrode column and the P-type semiconductor constitute an electrical connection.

8. The manufacturing method of a solar cell according to claim 6, wherein the distance between two adjacent microelectrode columns is not greater than the diffusion length T.

9. The manufacturing method of a solar cell according to claim 6, wherein the deep trench has two extension lines along both sides of the deep trench to form an acute angle.

10. A solar cell, comprising:
an N-type semiconductor;
a P-type semiconductor, tightly combined with the N-type semiconductor, and a PN junction being formed between the P-type semiconductor and the N-type semiconductor, and the N-type semiconductor including at least a deep trench;
a top electrode, coupled to the N-type semiconductor, and including at least a microelectrode column embedded into the deep trench; and
a bottom electrode, coupled to the P-type semiconductor;
wherein, when the N-type semiconductor has a diffusion length T, the distance between the PN junction and the upper end of the microelectrode column is not greater than half T.
